(19) United States
(12) Patent Application Publication
(10) Pub. No.: US 2026/0218365 A1
(43) Pub. Date: Jul. 30, 2026

(54) METAL PLATE AND DEPOSITION MASK COMPRISING SAME

(71) Applicant: LG INNOTEK CO., LTD., Seoul (KR)

(72) Inventors: Ki Young KWON, Seoul (KR); Kweon Jin LEE, Seoul (KR)

(21) Appl. No.: 19/145,025

(22) PCT Filed: Jan. 11, 2024
(86) PCT No.: PCT/KR2024/000555

§ 371 Date: Jul. 1, 2025

(30) Foreign Application Priority Data
Jan. 11, 2023 (KR) 10-2023-0004156

(51) Int. Cl. C23C 14/04; H10K 71/16

(52) U.S. Cl. CPC C23C 14/042; H10K 71/166

(57) ABSTRACT

A metal plate according to an embodiment includes a first region and a second region, the metal plate includes invar containing iron and nickel, the metal plate has a thickness of 20 μm to 50 μm, a thickness of the second region is smaller than a thickness of the first region, the first region and the second region include nickel of 40 wt % or less in a region from a surface of the metal plate to a depth of 2.5 μm, and a nickel content in a region from a first surface of the first region to a depth of 2.5 μm is smaller than a nickel content in a region from a second surface of the second region to a depth of 2.5 μm.

### TECHNICAL FIELD

An embodiment relates to a metal plate and a deposition mask including the same.

### BACKGROUND ART

A display device is applied to various devices. For example, the display device can be applied to small devices such as smartphones or tablet PCs and large devices such as TVs, monitors, or public displays (PDs). Recently, a demand for ultra-high definition (UHD) with an ultra-high resolution of 500 PPI (Pixel Per Inch) or higher has been increasing. Accordingly, interest in technologies for realizing low power and high resolution is increasing.

Generally used display devices may be largely classified into a liquid crystal display (LCD) and an organic light emitting diode (OLED) depending on a driving method.

The LCD is a display device driven using a liquid crystal. A light source including a cold cathode fluorescent lamp (CCFL) or a light emitting diode (LED) is placed below the liquid crystal. The LCD uses the liquid crystal to control an amount of light emitted from the light source.

In addition, the OLED is a display device driven using an organic matter. The OLED does not require a separate light source. In the OLED, the organic material itself may function as a light source and may be driven with low power consumption. In addition, the OLED can express an infinite contrast ratio and has a response speed that is about 1,000 times faster than that of the LCD. In addition, the OLED is receiving attention as a display device that can replace the LCD because of its excellent viewing angle.

The organic material included in a light-emitting layer in the OLED is deposited by a deposition mask called an open mask (OM) or a fine metal mask (FMM). The deposited organic material is formed in a pattern corresponding to the pattern formed in the deposition mask. Accordingly, the deposited organic material performs a role of a pixel.

The open mask is a thin plate that allows deposition only at a specific location during the manufacturing of the OLED display. The open mask is used in a deposition process to form a light-emitting layer on a backplane after the backplane is completed during a display manufacturing process. That is, the open mask is an open mask that does not have a covering region within a range where the display operates in order to deposit an entire display, and is also used when depositing a light-emitting layer with a light-emitting material of one color or when depositing layers such as EIL and HTL.

On the other hand, the fine metal mask is used to change a color of the sub-pixel of the light-emitting layer to be implemented, and for this purpose, an ultra-fine hole is formed. A process using the fine metal mask requires multiple stages of deposition, so precise alignment is required, and thus, it is more difficult than the technology using only the open mask.

When the light-emitting layer of the OLED display is deposited using the open mask, only one color can be emitted, so a separate layer such as a color filter (C/F) is required for color implementation. On the other hand, when a RGB light-emitting layer is formed using the fine metal mask, a separate color filter is not required. In other words, the technology that utilizes a fine metal mask for sub-pixels is difficult, but it has excellent light efficiency because it does not require a filter to block light compared to the method that utilizes an open mask.

The fine metal mask is manufactured from an Invar alloy metal plate containing iron (Fe) and nickel (Ni). At this time, a through hole penetrating the one surface and the other surface of the metal plate is formed, and the through hole can be formed at a position corresponding to a pixel pattern. Accordingly, organic materials such as red, green, and blue can pass through the through hole of the metal plate and be deposited on a substrate, and a pixel pattern can be formed on the substrate.

Meanwhile, before manufacturing the fine metal mask, a process of reducing a thickness of the metal plate can be performed. In addition, a process of polishing a surface of the metal plate can be performed.

Due to the above process, an internal composition of the metal plate can vary depending on regions of the metal plate. For example, one region of the metal plate can be changed to a region containing more nickel than iron.

Accordingly, etching characteristic of the metal plate can be changed. Accordingly, a size or shape of the through hole formed in the metal plate can become uneven. By this, a deposition quality of the deposition mask may be reduced.

Therefore, a metal plate and a deposition mask that can solve the above problems are required.

As a technology related to the deposition mask, Korean Publication No. KR10-2020-0058072 (2020.05.27) is disclosed.

### DISCLOSURE

### Technical Problem

An embodiment provides a metal plate having a uniform composition.

The embodiment provides a metal plate having improved deposition efficiency.

### Technical Solution

A metal plate according to an embodiment comprises a first region and a second region, wherein the metal plate includes invar containing iron and nickel, the metal plate has a thickness of 20 μm to 50 μm, a thickness of the second region is smaller than a thickness of the first region, the first region and the second region include nickel of 40 wt % or less in a region from a surface of the metal plate to a depth of 2.5 μm, and a nickel content in a region from a first surface of the first region to a depth of 2.5 μm is smaller than a nickel content in a region from a second surface of the second region to a depth of 2.5 μm.

A metal plate according to an embodiment comprises invar containing iron and nickel, wherein the thickness of the metal plate is 20 μm to 30 μm, the metal plate includes nickel of 40 wt % or less in a region from a surface of the metal plate to a depth of 2.5 μm, and the metal plate has a nickel weight deviation of 1 wt % to 6 wt % in a region from the surface of the metal plate to the depth of 2.5 μm.

### Advantageous Effects

The metal plate according to the embodiment can have improved surface characteristics.

In detail, the metal plate according to the embodiment can have a small size of surface roughness. In addition, the metal plate according to the embodiment can have a small thickness deviation.

The metal plate according to the embodiment can polish a surface of the metal plate before forming a through hole in the metal plate after a cold rolling process. Accordingly, a nickel content can be formed to be 40 wt % or less in a region from a surface of the metal plate to a set range of depth.

Therefore, etching characteristics of the metal plate can be prevented from changing due to different nickel contents in each region on the surface of the metal plate. Accordingly, when a thickness of the metal plate is further reduced, the thickness uniformity of the metal plate finally manufactured can be improved.

In addition, when forming a through hole in the metal plate, a shape and size of the through hole can be made uniform.

Accordingly, a deposition mask manufactured by the metal plate can have improved deposition reliability.

### DESCRIPTION OF DRAWINGS

FIG. 1 is a drawing for explaining a surface of a metal plate according to an embodiment after a first surface treatment process.

FIG. 2 is a drawing for explaining a surface of a metal plate according to an embodiment after a cold rolling process.

FIGS. 3 (a) and (b) is a drawing for explaining a surface of a metal plate according to an embodiment after a cold rolling process.

FIG. 4 is a drawing for explaining a region of a metal plate after a cold rolling process.

FIGS. 5 to 7 (b) are drawings for explaining a process for confirming a surface of a metal plate after a cold rolling process.

FIG. 8 is a drawing for explaining a second surface treatment process.

FIGS. 9 and 10 are drawings for explaining a metal plate manufactured through a second surface treatment process.

FIGS. 11 to 15 (b) are drawings for explaining characteristics of metal plates according to an embodiment and a comparative example.

FIG. 16 is a drawing for explaining that a deposition mask according to an embodiment is coupled to a frame.

FIG. 17 is a cross-sectional view showing an organic deposition device including a deposition mask according to an embodiment.

FIG. 18 is a drawing for explaining forming a deposition pattern on a deposition substrate using a deposition mask according to an embodiment.

FIG. 19 is a drawing showing a plan view of a deposition mask according to an embodiment.

FIG. 20 (a) to (c) is a drawing for explaining a defect in a through hole of a deposition mask according to an embodiment.

### BEST MODE

Hereinafter, embodiments will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and redisposed. In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art.

Further, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “connected” to another element, it may include not only when the element is directly “connected” to, “coupled” to, or “connected” to other elements, but also when the element is “connected”, “coupled”, or “connected” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

The deposition mask described below is a fine metal mask (FMM) capable of depositing red, green, and blue organic materials on a deposition substrate to form an RGB pixel pattern on the deposition substrate, and the following description does not apply to an open mask (OM).

In the following description, a first direction 1D is defined as a longitudinal direction of the metal plate or deposition mask, and a second direction 2D is defined as a width direction of the metal plate or deposition mask.

Hereinafter, a metal plate according to an embodiment and a deposition mask including the same will be described with reference to the drawings.

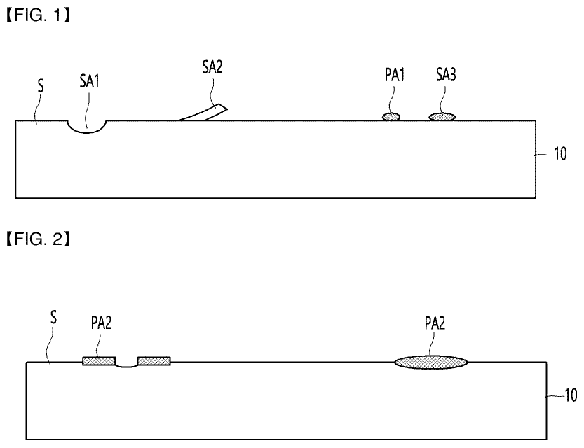

Preferentially, a metal plate according to an embodiment will be described with reference to FIGS. 1 to 10.

### Metal Plate and Manufacturing Method Thereof

The metal plate 10 according to an embodiment described below may be a raw material for manufacturing a deposition mask. For example, the deposition mask described below may be formed by forming a plurality of through holes in the metal plate 10.

The metal plate 10 may include an alloy. In detail, the metal plate 10 may include iron (Fe) and nickel (Ni). More specifically, the metal plate may include iron (Fe), nickel (Ni), oxygen (O), and chromium (Cr). In addition, the metal plate may further include at least one element from among a small amount of carbon (C), silicon (Si), sulfur S, phosphorus P, manganese (Mn), titanium (Ti), cobalt (Co), copper (Cu), silver (Ag), vanadium (V), niobium (Nb), indium (In), and antimony (Sb). For example, the metal plate 10 may include an Invar alloy.

The Invar is an alloy including iron and nickel. The Invar is a low thermal expansion alloy having a coefficient of thermal expansion close to 0. The Invar has a very small coefficient of thermal expansion. Accordingly, the Invar is used in precision parts such as masks and precision devices. Therefore, when a deposition mask is manufactured using the metal plate 10, deformation of the deposition mask can be prevented and the life of the deposition mask can be increased.

The metal plate 10 may include invar containing 60 wt % to 65 wt % of iron and 35 wt % to 40 wt % of nickel. In addition, the metal plate 10 may further include at least one element of carbon (C), silicon (Si), sulfur S, phosphorus P, manganese (Mn), titanium (Ti), cobalt (Co), copper (Cu), silver (Ag), vanadium (V), niobium (Nb), indium (In), and antimony (Sb) by 1 wt % or less.

The components, content, and weight % of the metal plate may be confirmed by selecting an arbitrary sample region on a plane of the metal plate 10 and sampling a specimen corresponding to a thickness of the metal plate 10. Then, the specimen may be dissolved in a strong acid or the like to confirm the weight % of each component. However, the embodiment is not limited thereto, and the components and weight % of the metal plate may be confirmed by various methods capable of confirming the composition of the metal plate.

The metal plate 10 may undergo a pretreatment process before forming the through hole. Specifically, a pretreatment process for reducing a thickness of the metal plate 10 may be performed. In addition, a pretreatment process for improving surface characteristics of the metal plate 10 may be performed.

A thickness of the metal plate 10 may reduce by the pretreatment process. In addition, a surface roughness of the metal plate 10 may reduce by the pretreatment process. In addition, a surface composition of the metal plate 10 may be changed by the pretreatment process. As a result, the metal plate may have a thin thickness and improved surface characteristics.

For example, the pretreatment process may include a thickness control process and a surface treatment process. The thickness control process may include a hot rolling process and a cold rolling process. Alternatively, the thickness control process may include a hot rolling process, a cold rolling process, and an etching process.

The surface treatment process includes a first surface treatment process and a second surface treatment process. The surface treatment process may be performed together with the thickness control process.

For example, the hot rolling process, the first surface treatment process, the cold rolling process, and the second surface treatment process may be performed sequentially.

Alternatively, the hot rolling process, the first surface treatment process, the cold rolling process, the second surface treatment process, and the etching process may be performed sequentially.

Hereinafter, a method for manufacturing the metal plate will be described.

First, the hot rolling process is performed. A thickness of the metal plate 10 is reduced by the hot rolling process. For example, the thickness of the metal plate 10 is reduced from a thickness exceeding 3 mm to a thickness of 3 mm or less.

Next, the first surface treatment process is performed.

The first surface treatment process is performed to remove surface inclusions of the metal plate 10. As a result, the surface characteristics of the metal plate 10 can be improved. The first surface treatment process may be performed by mechanical polishing using equipment such as a grinder. At this time, a scratch or burr may be generated on the surface S of the metal plate 10 by the first surface treatment process. Alternatively, by-products such as particles may be generated by the first surface treatment process, and the by-products may be attached to the surface of the metal plate 10.

For example, referring to FIG. 1, a concave region SA1 may be formed on the surface S of the metal plate where the surface S of the metal plate is partially removed by the scratch. Alternatively, a region SA2 lifted from the surface S of the metal plate may be formed on the surface S of the metal plate by the burr. Alternatively, a region SA3 to which the by-product is attached may be formed on the surface S of the metal plate.

Therefore, a plurality of protruding regions PA1 can be formed on the metal plate 10 by the concave region SA1, the lifting region SA2, and the region SA3 to which the by-products is attached.

Subsequently, the cold rolling process is performed. A thickness of the metal plate 10 is reduced by the cold rolling process. For example, the thickness of the metal plate 10 after the cold rolling is reduced to a thickness of 50 μm or less. In detail, the thickness of the metal plate 10 after the cold rolling is reduced to a thickness of 40 μm to 50 μm.

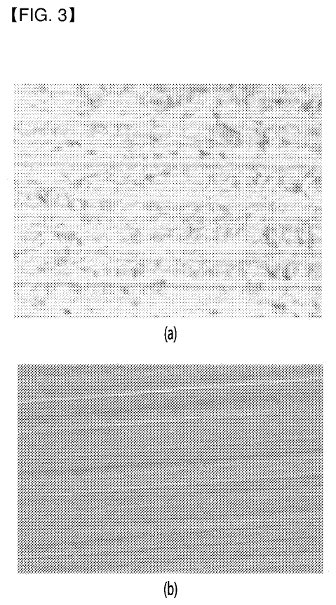

When the metal plate 10 including the protruding region PA1 is cold rolled, the protruding region PA1 can be pressed into the surface S of the metal plate 10 by pressure. By this, referring to FIG. 2, a plurality of pressing regions PA2 in which the protruding region PA1 is pressed can be formed on the surface S of the metal plate 10.

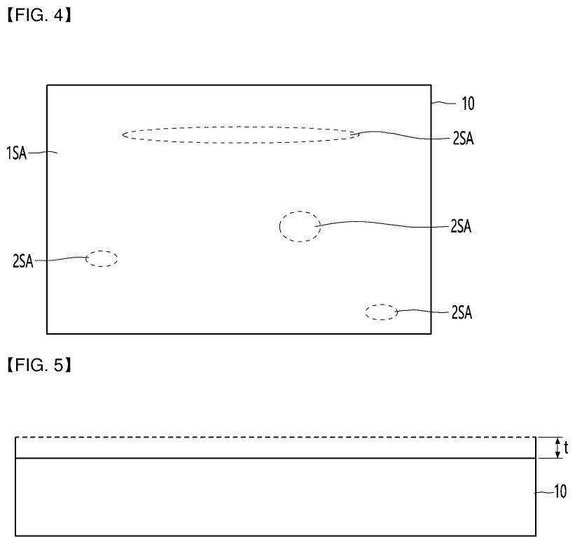

FIG. 3 is a drawing for explaining the surface of the metal plate 10. FIG. 3 (a) is a photograph taken of the metal plate 10 after cold rolling using an optical microscope. FIG. 3 (b) is a photograph analyzed of the metal plate 10 after cold rolling using a scanning electron microscope (SEM).

Referring to FIG. 3, the surface characteristics of the metal plate may be reduced by the pressing region PA2. For example, a surface thickness of the metal plate may become uneven due to the pressing region PA, and a surface roughness of the metal plate may increase.

The pressing region PA2 may have a higher nickel (Ni) content than other regions. Specifically, the pressing region PA2 may have a higher nickel content than regions other than the pressing region PA2. Specifically, the pressing region PA2 forms a nickel (Ni) concentration layer by a following reaction formula, and thus a nickel content may be increased.

$$4 FeO -> Fe 3 O 4 + Fe \\ NiO + Fe -> FeO + Ni \qquad [ Reaction formula ]$$

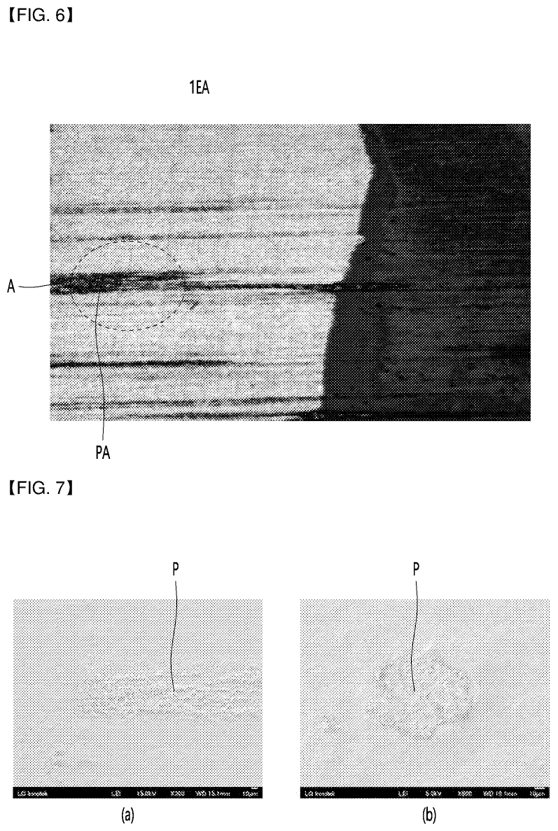

Accordingly, referring to FIG. 4, after the cold rolling, the metal plate 10 may include a first surface region 1SA and a second surface region 2SA.

The first surface region 1SA may be defined as a region having a small nickel content. Specifically, the first surface region 1SA may be defined as a region having a nickel content of 40 wt % or less. In addition, the first surface region 1SA may be defined as a region having an iron (Fe) content of 60 wt % or more.

The second surface region 2SA may be defined as a region having a large nickel content. Specifically, the second surface region 2SA may be defined as a region having a nickel content of more than 40 wt %. In addition, the second surface region 2SA may be defined as a region having an iron (Fe) content of less than 60 wt %. The second surface region 2SA may have a nickel content greater than that of the first surface region 2SA due to the pressing region PA2.

Accordingly, when a process of forming a through hole in a metal plate is performed after the cold rolling process, a difference in etching rate may occur in the first surface region 1SA and the second surface region 2SA. Specifically, the first surface region 1SA may have a fast etching rate because an iron content is high and a nickel content is low. However, the second surface region 2SA may have a slow etching rate because an iron content is low and a nickel content is high.

Therefore, when forming a through hole in the metal plate 10, an amount of etching varies depending on regions of the metal plate, so a defect in the through hole may occur.

Alternatively, when etching the metal plate to further reduce the thickness of the metal plate 10, an amount of etching may vary depending on regions of the metal plate. As a result, the thickness of the second surface region 2SA may become thicker than that of the first surface region 1SA. Accordingly, when forming a through hole in the metal plate 10, the etching uniformity may be reduced due to a difference in the thickness of the metal plate. Therefore, a shape or size of the through hole of the deposition mask may become non-uniform. As a result, the deposition efficiency of the deposition mask may be reduced.

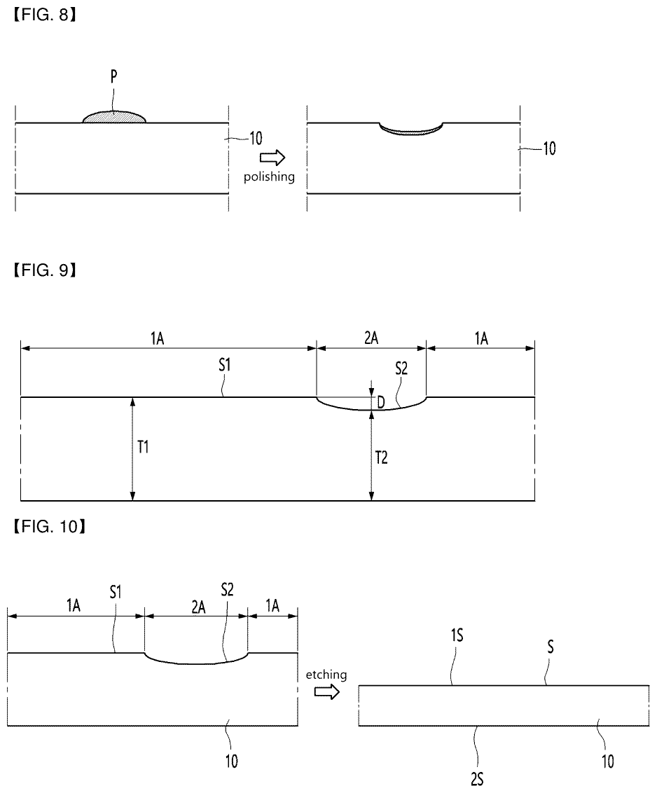

FIGS. 5 to 7 are drawings for explaining the surface change of the metal plate after the cold rolling process.

Referring to FIG. 5, a cold-rolled metal plate 10 is prepared. Then, the metal plate 10 is etched to a thickness (t) within a set range.

FIG. 6 is a photograph of the cold-rolled metal plate 10 after etching. FIG. 7 is a scanning electron microscope (SEM) photograph of region A of FIG. 6.

Referring to FIG. 6, a line-shaped pattern or a dot-shaped pattern is confirmed on the metal plate 10. The patterns PA are formed by a nickel-concentration layer. That is, after the cold rolling process, a nickel-rich region is formed on the surface of the metal plate. That is, after the cold rolling process, a nickel-rich region is formed in the metal plate 10.

Referring to FIG. 7, the pattern PA includes a plurality of protrusions P. The protrusions P are formed in a line shape or a dot shape. A composition ratio of the region where the protrusions P are formed is different from the composition ratios of other regions. Specifically, the region where the protrusions P are formed has a greater nickel content than other regions.

That is, the metal plate 10 forms a nickel-rich region after the cold rolling process.

In order to solve the above problem, the metal plate according to the embodiment may additionally proceed with a second surface treatment process after the cold rolling process.

In the second surface treatment process, the metal plate 10 may be polished. Specifically, an entire surface of the metal plate 10 may be polished. For example, the metal plate can be polished by mechanical polishing or chemical polishing.

In detail, in the second surface treatment process, the surface of the metal plate 10 can be polished to a thickness of 0.4 μm or less. For example, the surface of the metal plate 10 can be polished to a thickness of 0.2 μm to 0.4 μm.

The nickel concentration layer can be removed by the second surface treatment process.

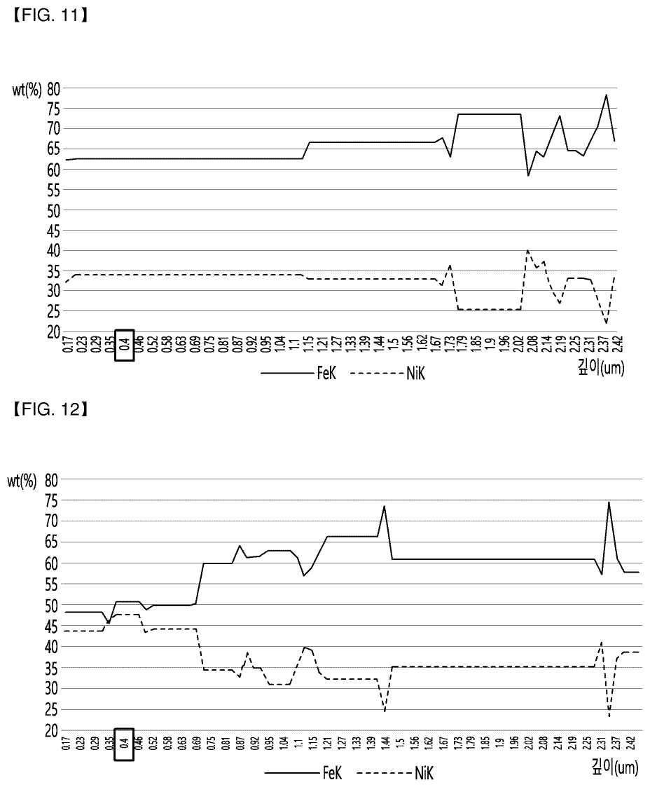

Referring to FIG. 8, the protrusion P can be removed. In detail, the nickel concentration layer of the metal plate 10 can be removed.

Therefore, the surface of the metal plate 10 has a uniform composition ratio as a whole. As a result, the surface characteristics of the metal plate 10 can be improved.

By the second surface treatment process performed after the cold rolling process, the metal plate 10 can have improved surface characteristics.

Next, an etching process is performed. In the etching process, an entire surface of the metal plate 10 is etched. The thickness of the metal plate 10 is reduced by the etching process. Specifically, the thickness of the metal plate is reduced to 30 μm or less by the etching process. More specifically, the thickness of the metal plate is reduced to 20 μm to 30 μm by the etching process.

The etching process may be omitted. Specifically, the thickness of the metal plate 10 may be reduced by the second surface treatment process. For example, the thickness of the metal plate 10 may be reduced to 20 μm to 30 μm by the second surface treatment process.

The metal plate according to the embodiment has improved surface characteristics. Specifically, the protrusion is removed by the second surface treatment process. Accordingly, the surface composition of the metal plate may become uniform. In addition, the surface roughness of the metal plate may become uniform.

Accordingly, when forming a through hole in the metal plate, the size or shape of the through hole can be made uniform.

In addition, when additionally etching the metal plate, the thickness of the metal plate can be etched uniformly. In addition, the surface composition and surface roughness of the metal plate can be made uniform after the etching process.

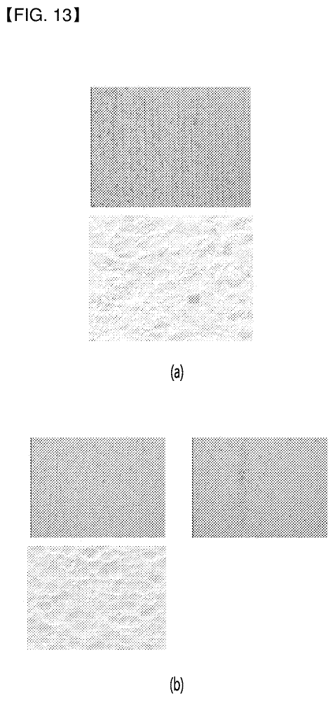

FIG. 9 is a drawing showing a cross-sectional view of a metal plate manufactured by a process omitting the etching process.

Referring to FIG. 9, when a metal plate is manufactured by the process, the metal plate may include a first region 1A and a second region 2A. The second region 2A is defined as a region from which a nickel concentration layer is removed through the second surface treatment process.

After the second surface treatment process, the thickness of the metal plate 10 may be 20 μm to 50 μm. The surface of the metal plate 10 may be divided into two surfaces. For example, the first region 1A may have a first surface S1, and the second region 2A may have a second surface S2.

The first region 1A and the second region 2A may have different thicknesses. In detail, the thickness T1 of the first region 1A may be greater than the thickness of the second region 2A. For example, the difference (D) between the thickness T1 of the first region 1A and the thickness of the second region 2A may be greater than 0 μm and less than or equal to 0.5 μm.

A nickel content in a region from the first surface S1 to a depth of 2.5 μm may be 40 wt % or less. In addition, a nickel content in a region from the second surface S2 to a depth of 2.5 μm may be 40 wt % or less.

The first region 1A and the second region 2A may have different composition ratios. In detail, the first region 1A and the second region 2A may have different nickel contents. In addition, the first region 1A and the second region 2A may have different iron contents.

In detail, the nickel content in the region from the first surface S1 to a depth of 2.5 μm may be smaller than the nickel content in the region from the second surface S2 to a depth of 2.5 μm. For example, a difference between the nickel content in the region from the first surface S1 to a depth of 2.5 μm and the nickel content in the region from the second surface S2 to a depth of 2.5 μm may be 6 wt % or less, 4 wt % or less, or 2 wt % or less. In detail, the difference between the nickel content in the region from the first surface S1 to a depth of 2.5 μm and the nickel content in the region from the second surface S2 to a depth of 2.5 μm may be 1 wt % to 6 wt %.

In addition, the iron content in the region from the first surface S1 to a depth of 2.5 μm may be greater than the iron content in the region from the second surface S2 to a depth of 2.5 μm. For example, a difference between the iron content in the region from the first surface S1 to a depth of 2.5 μm and the iron content in the region from the second surface S2 to a depth of 2.5 μm may be 6 wt % or less, 4 wt % or less, or 2 wt % or less. In detail, the difference between the iron content in the region from the first surface S1 to a depth of 2.5 μm and the iron content in the region from the second surface S2 to a depth of 2.5 μm may be 1 wt % to 6 wt %.

The second region 2A is a region from which the nickel concentration layer has been removed, and the nickel content may be large and the iron content may be small due to a remaining nickel concentration layer.

The nickel content and the nickel content deviation in the region from the surface S of the metal plate to a depth of 2.5 μm may be controlled.

Accordingly, the surface composition may be uniform in all regions of the metal plate. That is, the difference in nickel weight % and the difference in iron weight % in the region from the surface of the metal plate to a depth of 2.5 μm are reduced. Accordingly, when forming a through hole in the metal plate, a difference in etching rate according to the difference in nickel weight % and the difference in iron weight % can be reduced. Therefore, the deviation in the shape and size of the through hole formed in the metal plate can be reduced.

The first region 1A and the second region 2A may have different surface roughnesses. In detail, the first surface S1 and the second surface 2S may have different roughnesses. In detail, the surface roughness of the second region may be smaller than the surface roughness of the first region. The second region 2A is a region where the nickel concentration layer is removed by polishing. Accordingly, the surface roughness of the second region 2A may be smaller than that of the first region 1A.

FIG. 10 is a drawing showing a cross-sectional view of a metal plate manufactured by performing an etching process after a second surface treatment process.

After the etching process, the thickness of the metal plate 10 may be 20 μm to 30 μm.

The metal plate 10 may include nickel and iron in a set weight % range in a region from the surface S of the metal plate 10 to a depth of 2.5 μm.

In detail, the nickel content in the depth region from the surface S of the metal plate 10 to 2.5 μm may be 40 wt % or less. In addition, the difference in the nickel content in the region from the surface S of the metal plate 10 to a depth of 2.5 μm may be 6 wt % or less, 4 wt % or less, or 2 wt % or less. For example, the difference in the nickel content in the region from the surface S of the metal plate 10 to a depth of 2.5 μm may be 1 wt % to 6 wt %.

In addition, the iron content in the region from the surface S of the metal plate 10 to a depth of 2.5 μm may be 60 wt % or more. In detail, the iron content in the region from the surface S of the metal plate 10 to a depth of 2.5 μm may be 60 wt % to 64 wt %. In addition, the difference in the iron content in the region from the surface S of the metal plate 10 to a depth of 2.5 μm may be 6 wt % or less, 4 wt % or less, or 2 wt % or less. For example, the difference in the iron content in the depth region from the surface S of the metal plate 10 to 2.5 μm may be 1 wt % to 6 wt %.

Any two sample regions may be selected from the surface S of the metal plate 10. A difference in the nickel wt % and iron wt % measured in the region from the surface to the depth of 2.5 μm of each sample region may have a set range.

In detail, a difference in nickel weight % measured in the region from the surface of each sample region to a depth of 2.5 μm may be 6 wt % or less, 4 wt % or less, or 2 wt % or less. For example, the difference in nickel weight % measured in the region from the surface of each sample region to a depth of 2.5 μm may be 1 wt % to 6 wt %.

In addition, the difference in iron weight % measured in the region from the surface of each sample region to a depth of 2.5 μm may be 6 wt % or less, 4 wt % or less, or 2 wt % or less. For example, the difference in iron weight % measured in the region from the surface of each sample region to a depth of 2.5 μm may be 1 wt % to 6 wt %.

Alternatively, the metal plate 10 may have an average nickel wt % and an average iron wt % within a set range in a region from the surface S of the metal plate 10 to a depth of 2.5 μm. The average nickel wt % may be defined as a value obtained by selecting n sample regions from the surface S of the metal plate 10 and dividing the sum of the nickel wt % s measured in each sample region by n. In addition, the average iron wt % may be defined as a value obtained by selecting n sample regions from the surface S of the metal plate 10 and dividing the sum of the iron wt % s measured in each sample region by n.

The average nickel wt % in the region from the surface S of the metal plate 10 to a depth of 2.5 μm may be 36 wt % to 40 wt %. In addition, the average iron wt % in the region from the surface S of the metal plate 10 to a depth of 2.5 μm may be 64 wt % to 36 wt %.

The metal plate 10 may have a surface roughness within a set range.

Specifically, the metal plate 10 may include a first surface 1S and a second surface 2S opposite to the first surface 1S. The first surface 1S may be defined as a surface on which the metal plate 10 is surface-treated.

The first surface 1S and the second surface 2S may have different surface roughnesses. Specifically, the surface roughness of the first surface 1S may be smaller than the surface roughness of the second surface 2S. For example, a minimum arithmetic mean roughness (Ra) of the first surface 1S may be 30 nm to 59 nm. In addition, a minimum 10-point average roughness (Rz) of the first surface 1S may be 0.5 nm to 0.79 nm.

In addition, the metal plate may have a thickness deviation within a set range. The thickness deviation of the metal plate may be defined as a ratio of a maximum value and a minimum value of the metal plate. The metal plate may have a thickness deviation of 3% or less in the first direction and the second direction.

Since the metal plate 10 may be etched to a uniform thickness through a second surface treatment process, the metal plate may have a small surface roughness and improve the thickness uniformity.

The metal plate 10 may include nickel and iron in a set range in a region from the surface of the metal plate to a depth of 2.5 μm. In addition, the metal plate 10 may have a nickel weight % deviation and iron weight % deviation in a set range in a region from the surface of the metal plate to a depth of 2.5 μm.

Accordingly, the surface composition of the metal plate may be uniform in an entire region of the metal plate. That is, a difference in the nickel and iron weight % in the region from the surface of the metal plate to a depth of 2.5 μm may be reduced. Accordingly, when forming a through hole in the metal plate, a difference in etching rate according to a difference in weight % of nickel and iron can be reduced. Therefore, the deviation in the shape and size of the through hole formed in the metal plate can be reduced.

Hereinafter, the present invention will be described in more detail through examples and comparative examples.

### Example 1

An Invar metal plate having a thickness of 3 mm was manufactured.

Subsequently, a hot rolling process, a first surface treatment process, a cold rolling process, and a second surface treatment process were sequentially performed. As a result, a metal plate having a thickness of 40 μm was manufactured.

At this time, the first surface treatment process was performed by grinding the surface of the metal plate using a grinder.

In addition, the second surface treatment process was performed by chemical polishing or mechanical polishing.

Subsequently, an arbitrary region of the metal plate was sampled as a specimen, and the nickel and iron contents of the metal plate were measured by dissolving the specimen in a strong acid.

### Example 2

After the second surface treatment process, the metal plate was additionally etched. Accordingly, a metal plate was manufactured in the same manner as in Example 1, except that a metal plate having a thickness of 20 μm was manufactured.

Subsequently, an arbitrary region of the metal plate was sampled as a specimen, and the nickel and iron contents of the metal plate were measured by dissolving the specimen in a strong acid.

### Comparative Example 1

A metal plate was manufactured in the same manner as in Example 1, except that the second surface treatment process was not performed.

Subsequently, a pattern region was sampled as a specimen, and the nickel and iron contents of the metal plate were measured by dissolving the specimen in a strong acid.

### Comparative Example 2

A metal plate was manufactured in the same manner as in Example 2, except that the second surface treatment process was not performed.

Subsequently, an arbitrary region of the metal plate was sampled as a specimen, and the nickel and iron contents of the metal plate were measured by dissolving the specimen in a strong acid.

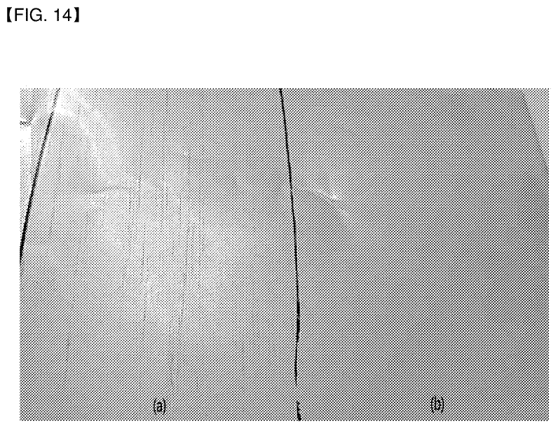

FIG. 11 is a graph showing the contents of iron and nickel of the metal plates according to Examples 1 and 2. In addition, FIG. 12 is a graph showing the contents of iron and nickel of the metal plates according to Comparative Examples 1 and 2.

Referring to FIG. 11, the metal plate according to the example has a nickel content of 40 wt % or less and an iron content of 60 wt % in a depth region from the surface to 2.5 μm.

On the other hand, referring to FIG. 12, the metal plate according to the comparative example includes a region in which the nickel content exceeds 40 wt % and an iron content is less than 60 wt % in a depth region from the surface to 2.5 μm.

The metal plate according to the example undergoes a second surface treatment process to remove a region containing a large amount of nickel. Accordingly, the metal plate according to the example can have a nickel content of 40 wt % or less and an iron content of 60 wt % in a region from the surface to 2.5 μm.

On the other hand, the metal plate according to the embodiment does not undergo a second surface treatment process for removing a region containing a large amount of nickel. Accordingly, the metal plate according to the comparative example includes a region in which the nickel content exceeds 40 wt % and the iron content is less than 60 wt % in a depth region from the surface to 2.5 μm due to the nickel concentration layer.

Accordingly, the embodiment and the comparative example may have different surface characteristics. FIGS. 13 to 15 are drawings illustrating surface photographs of the metal plates according to the embodiment and the comparative example. (a) of FIGS. 13, 14, and 15 is a surface photograph of the metal plate according to the comparative example, and (b) of FIGS. 13, 14, and 15 is a surface photograph of the metal plate according to the embodiment.

Referring to FIGS. 15 to 17, the metal plate according to the comparative example may have a large surface roughness due to a protrusion formed by the nickel concentration layer. In addition, the metal plate according to the comparative example may have a small thickness uniformity due to a protrusion formed by the nickel concentration layer.

On the other hand, the metal plate according to the embodiment can have a small surface roughness and improve the thickness uniformity because the nickel concentration layer is removed.

### Deposition Mask

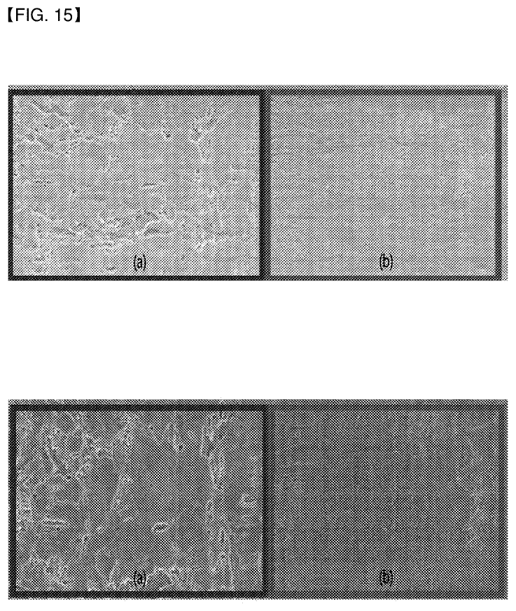

Hereinafter, the deposition mask according to the embodiment will be described with reference to FIGS. 16 to 18.

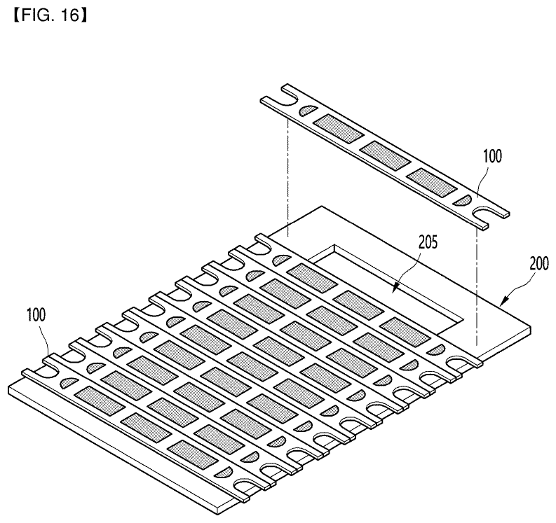

Referring to FIGS. 16 and 17, an organic deposition device includes a deposition mask 100, a mask frame 200, a deposition substrate 300, an organic material deposition container 400, and a vacuum chamber 500.

The deposition mask 100 can be formed using the metal plate 10 described above. The deposition mask 100 includes a plurality of through holes TH formed in an effective portion for deposition. At this time, the through holes are formed to correspond to a pattern to be formed on the deposition substrate. That is, the deposition mask 100 includes a metal plate 10, and a plurality of through holes TH can be formed in the metal plate 10.

The mask frame 200 includes an opening 205. A plurality of through holes of the deposition mask 100 are disposed in a region corresponding to the opening 205 of the mask frame 200. Accordingly, an organic material supplied to the organic material deposition container 400 is deposited on the deposition substrate 300. The deposition mask 100 is disposed and fixed on the mask frame 200. For example, the deposition mask 100 may be tensioned with a set tensile force and welded and fixed on the mask frame 200.

For example, the deposition mask 100 may be fixed to the mask frame 200 by welding the non-deposition region of the deposition mask 100. Subsequently, a portion of the deposition mask 100 disposed at an outside of the mask frame 200 is removed by a method such as cutting.

The mask frame 200 is manufactured from a material that is less deformed when the deposition mask 100 is welded, for example, a metal with high rigidity.

The deposition substrate 300 is a substrate used in the manufacture of a display device. For example, the deposition substrate 300 may be a substrate for organic material deposition for an OLED pixel pattern. Organic material patterns of red, green, and blue are formed on the deposition substrate 300 to form pixels, which are the three primary colors of light. That is, an RGB pattern may be formed on the deposition substrate 300.

The organic material deposition container 400 is a crucible. An organic material is placed inside the crucible. The organic material deposition container 400 moves within a vacuum chamber 500. That is, the organic material deposition container 400 moves in one direction within the vacuum chamber 500. For example, the organic deposition container 400 moves in a width direction of the deposition mask 100 within the vacuum chamber 500. That is, the organic deposition container 400 moves in a direction perpendicular to a longitudinal direction of the deposition mask 100 within the vacuum chamber 500.

As a heat source and/or current is supplied to the crucible, which is the organic deposition container 400, within the vacuum chamber 500, the organic material is deposited on the deposition substrate 300.

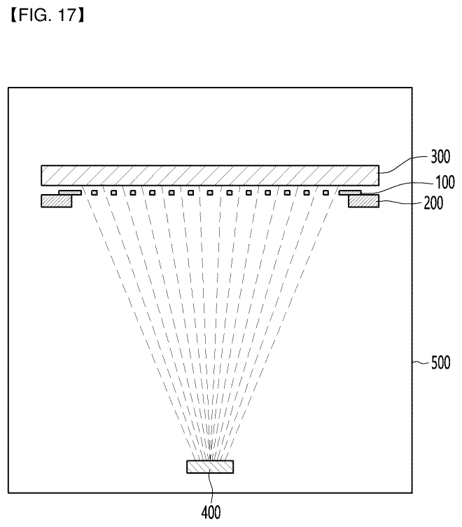

Referring to FIG. 18, the deposition mask 100 includes a first surface 1S and a second surface 2S opposite to the first surface,

The first surface 1S includes a small-area hole V1, and the second surface 2S includes a large-area hole V2. For example, each of the first surface 1S and the second surface 2S includes a plurality of small-area holes V1 and a plurality of large-area holes V2.

In addition, the deposition mask 100 includes a through hole TH. The through hole TH is connected by a communication part CA connecting the boundaries of the small-area hole V1 and the large-area hole V2.

A width of the large-area hole V2 is larger than a width of the small-area hole V1. At this time, the width of the small-area hole V1 is measured on the first surface 1S of the deposition mask 100, and the width of the large-area hole V2 is measured on the second surface 2S of the deposition mask 100.

In addition, the width of the communication part CA has a set size. In detail, the width of the communication part CA may be 15 μm to about 33 μm. More specifically, the width of the communication part CA may be 19 μm to about 33 μm. More specifically, the width of the communication part CA may be 20 μm to about 27 μm. If the width of the communication part CA exceeds 33 μm, it may be difficult to implement a resolution of 500 PPI or higher. In addition, if the width of the communication part CA is less than 15 μm, a deposition defect may occur.

The small-area hole V1 is disposed toward the deposition substrate 300. The small-area hole V1 is disposed close to the substrate 300. Accordingly, the small-area hole V1 has a shape corresponding to the deposition material, i.e., the deposition pattern DP.

The large-area hole V2 is disposed toward the organic material deposition container 400. Accordingly, the large-area hole V2 can accommodate the organic material supplied from the organic material deposition container 400 in a wide width, and a fine pattern can be quickly formed on the deposition substrate 300 through the small-area hole V1 having a smaller width than the large-area hole V2.

Accordingly, the organic material accommodated through the large-area hole V1 is deposited on the deposition substrate 300 through the small-area hole V1. Accordingly, one of the red, green, or blue pixel patterns is formed on the deposition substrate 300. Subsequently, all of the red, green, or blue pixel patterns can be formed on the deposition substrate 300 by repeating the above process.

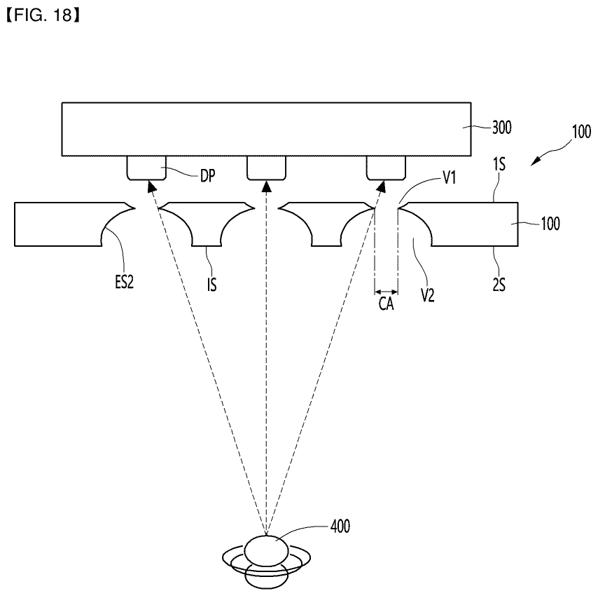

FIG. 19 is a drawing showing a plan view of a deposition mask 100 according to an embodiment.

Referring to FIG. 19, the deposition mask 100 according to an embodiment may include a deposition region DA and a non-deposition region NDA.

The deposition region DA is a region for forming a deposition pattern. The deposition region DA may include an effective region AA and an ineffective region UA. The effective region AA is defined as a region where a through hole TH through which the organic material passes is formed. In addition, the ineffective region UA is defined as a region where a through hole TH through which the organic material passes is not formed. In addition, the ineffective region UA is defined as a region where the through hole TH is formed, but the through hole TH of the ineffective region UA is defined as a region where the organic material does not pass.

In the drawing, the effective region AA is illustrated as a square shape, but the embodiment is not limited thereto, and the effective region AA may have a rectangular, circular, or oval shape.

The effective region AA may include a plurality of effective regions. The plurality of effective regions may be disposed to be spaced apart from each other in the longitudinal direction of the deposition mask.

The deposition region DA may be defined as a region from a point where a first effective region begins in the longitudinal direction of the deposition mask 100 to a point where a last effective region ends.

In addition, the deposition region DA may be defined as a region from a point where a first ineffective region begins in the longitudinal direction of the deposition mask 100 to a point where a last ineffective region ends.

The ineffective region UA may be defined as a region other than the effective region AA in the deposition region DA. The ineffective region UA may be divided into a first ineffective region UA1 and a second ineffective region UA2 according to a position of the ineffective region.

The first ineffective region UA1 may be defined as a region between the effective region AA. Accordingly, a plurality of first ineffective regions UA1 may be disposed to be spaced apart in the longitudinal direction of the deposition mask 100. In addition, the second ineffective region UA2 may be defined as a region between the effective region AA and both ends of the width direction of the deposition mask 100.

The non-deposition region NDA is a region that does not participate in deposition. The non-deposition region NDA may include a frame fixing region for fixing the deposition mask 100 to the mask frame 200. In addition, the non-deposition region NDA may include at least one of a half-etched portion and an open portion OA. The half-etched portion may be formed by partially etching the metal plate 10. In addition, the open portion OA may be formed by completely etching the metal plate 10.

The half-etched portion may disperse residual stress generated when tensioning the deposition mask 100. Accordingly, waviness of the deposition mask may be reduced.

In addition, the open portion OA is a region for fixing a jig such as a clamp when tensioning the deposition mask 100.

The through hole TH described above may be disposed in the effective region AA. In detail, the effective region AA may include a through hole TH including the small-area hole V1, the large-area hole V2, and a communication part CA connecting the small-area hole V1 and the large-area hole V2.

Since the deposition mask is manufactured by the metal plate 10 described above, it may have a content of nickel and iron, surface roughness, and thickness uniformity within a set range.

For example, a specimen SM may be measured in any region of the deposition mask. For example, the specimen S may be sampled in at least one region among the non-deposition region NDA, the first ineffective region UA1, and the second ineffective region UA2. When the composition, surface roughness, and thickness of the specimen are measured, the deposition mask may have a content of nickel and iron, surface roughness, and thickness uniformity within a set range corresponding the metal plate described above.

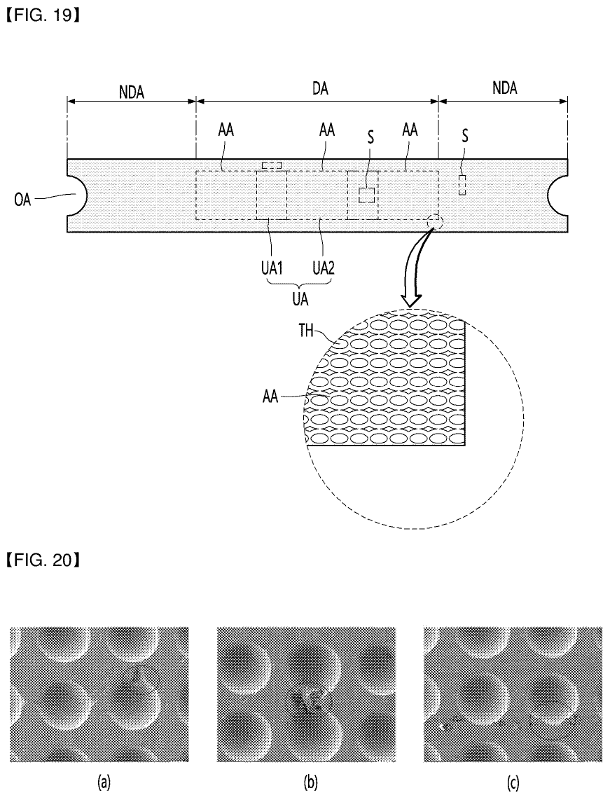

If the nickel content and iron content of the deposition mask are out of the above range, the difference in etching uniformity may increase when forming a through hole. As a result, the defect of the through hole of the deposition mask may increase. That is, as illustrated in FIG. 20, a defective through hole may be formed in which the size of the through hole is larger or smaller than that of another through hole due to the inclusion, or a defective through hole in which the through holes are connected to each other may be formed.

Accordingly, when forming a deposition pattern on a deposition substrate through the deposition mask, the deposition quality may decrease.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A metal plate including invar containing iron and nickel, the metal plate comprising:
wherein the metal plate includes a first region and a second region having different thicknesses in a range of 20 μm to 50 μm,
wherein the first region and the second region include nickel of 40 wt % or less in a region from a surface of the metal plate to a depth of 2.5 μm, and
wherein a nickel content in a region from a first surface of the first region to a depth of 2.5 μm and a nickel content in a region from a second surface of the second region to a depth of 2.5 μm are different from each other.

2-10. (canceled)

11. The metal plate of claim 1, wherein a thickness of the first region is greater than that of the second region, and
wherein the nickel content in the region from the first surface of the first region to a depth of 2.5 μm is smaller than the nickel content in the region from the second surface of the second region to a depth of 2.5 μm.

12. The metal plate of claim 11, wherein a difference between the nickel content in the region from the first surface of the first region to the depth of 2.5 μm and the nickel content in the region from the second surface of the second region to the depth of 2.5 μm is 1 wt % to 6 wt %.

13. The metal plate of claim 11, wherein a thickness difference between the first region and the second region is greater than Oum and less than 0.5 μm.

14. The metal plate of claim 1, wherein a roughness of the second surface is smaller than a roughness of the first surface.

15. The metal plate of claim 1, wherein the second region includes a concave surface that is concave toward a downward direction.

16. A metal plate including invar containing iron and nickel, the metal plate comprising:
wherein the thickness of the metal plate is 20 μm to 30 μm,
wherein the metal plate includes nickel of 40 wt % or less in a region from a surface of the metal plate to a depth of 2.5 μm,
wherein the metal plate includes regions having different thicknesses, and
wherein the regions having different thicknesses has a nickel weight deviation of 1 wt % to 6 wt % in a thickness direction.

17. The metal plate of claim 16, wherein the nickel weight deviation is a weight deviation of nickel contents from a surface of each of the regions having different thicknesses to a depth of 2.5 μm.

18. The metal plate of claim 16, wherein two random sample regions are selected from the surface of the metal plate,
wherein the two sample regions have different thicknesses, and
wherein a deviation of nickel weight % measured from a surface of each sample region to a depth of 2.5 μm is 1 wt % to 6 wt %.

19. The metal plate of claim 18, wherein the two sample regions include a first sample region having a first thickness, and a second sample region having a second thickness smaller than the first thickness, and
wherein a nickel content in a region from a surface of the first sample region to a depth of 2.5 μm is smaller than a nickel content in a region from a surface of the second sample region to a depth of 2.5 μm.

20. The metal plate of claim 14, wherein when n sample regions having different thicknesses are selected from the surface of the metal plate and a sum of nickel wt % measured in each of the n sample regions divided by n is defined as average nickel wt %, the average nickel weight % in a region from the surface of the metal plate to a depth of 2.5 μm is 36 to 40 wt %.

21. The metal plate of claim 16, wherein the metal plate includes a first surface and a second surface opposite to the first surface,
wherein a minimum arithmetic mean roughness (Ra) of the first surface is 30 nm to 59 nm, and
wherein a minimum 10-point average roughness (Rz) of the first surface is 0.5 nm to 0.79 nm.

22. The metal plate of claim 16, wherein the metal plate has a thickness deviation defined by a ratio of a maximum thickness value and a minimum thickness value, and
wherein the thickness deviation of the metal plate is 3% or less.

23. A deposition mask comprising:
a metal plate including a deposition region and a non-deposition region,
wherein the deposition region includes an effective region in which a through hole is formed and an ineffective region other than the effective region,
wherein the through hole is formed by a small-area hole; a large-area hole; and a communication part connecting the small-area hole and the large-area hole,
wherein the metal plate includes invar containing iron and nickel,
wherein at least one of the deposition region and the non-deposition region of the metal plate includes a first region and a second region having different thicknesses in a range of 20 μm to 50 μm,
wherein the first region and the second region include nickel of 40 wt % or less in a region from a surface of the metal plate to a depth of 2.5 μm, and
wherein a nickel content in a region from a first surface of the first region to a depth of 2.5 μm and a nickel content in a region from a second surface of the second region to a depth of 2.5 μm are different from each other.

24. The deposition mask of claim 23, wherein a thickness of the first region is greater than that of the second region, and
wherein the nickel content in the region from the first surface of the first region to a depth of 2.5 μm is smaller than the nickel content in the region from the second surface of the second region to a depth of 2.5 μm.

25. The deposition mask of claim 24, wherein a difference between the nickel content in the region from the first surface of the first region to the depth of 2.5 μm and the nickel content in the region from the second surface of the second region to the depth of 2.5 μm is 1 wt % to 6 wt %.

26. The deposition mask of claim 24, wherein a thickness difference between the first region and the second region is greater than Oum and less than 0.5 μm.

27. The deposition mask of claim 24, wherein a roughness of the second surface is smaller than a roughness of the first surface.

28. The deposition mask of claim 24, wherein the second region includes a concave surface that is concave toward a downward direction.
